(19) United States
(12) Patent Application Publication
(10) Pub. No.: US 2026/0362907 A1
(43) Pub. Date: Nov. 12, 2026

(54) DISPLAY PANEL AND DISPLAY APPARATUS

(71) Applicants: Chengdu BOE Optoelectronics Technology Co., Ltd., Chengdu, Sichuan Province (CN); BOE Technology Group Co., Ltd., Beijing (CN); Beijing BOE Technology Development Co., Ltd., Beijing (CN)

(72) Inventors: Ruqin ZHANG, Beijing (CN); Bingchuan LI, Beijing (CN); Tiancheng YU, Beijing (CN); Yige QI, Beijing (CN); Gaokun HUANG, Beijing (CN); Luyao WANG, Beijing (CN)

(21) Appl. No.: 19/470,249

(22) PCT Filed: Sep. 2, 2024
(86) PCT No.: PCT/CN2024/116304

§ 371 Date: Sep. 29, 2025

(30) Foreign Application Priority Data
Oct. 31, 2023 (CN) 202311432802.5

(51) Int. Cl. H10K 59/122; H10K 59/80

(52) U.S. Cl. CPC H10K 59/122; H10K 59/8792

(57) ABSTRACT

A display panel includes a base substrate, light-emitting devices, a pixel definition layer, and a light-shielding layer. The light-emitting devices include an anode, a light-emitting functional layer, and a cathode. The pixel definition layer includes first opening regions and is divided into first and second pixel definition layers including first and second side surfaces. First and second angles are provided between the first and second side surfaces and a plane where the base substrate is located. The first and second angles are both greater than 0° and less than 90°, and the second angle is less than the first angle. The light-shielding layer includes second opening regions. The orthographic projection of the second opening regions overlaps the orthographic projection of the first opening regions. The orthographic projection of the light shielding layer covers at least part of the orthographic projection of the second side surface.

### CROSS-REFERENCE TO RELATED APPLICATIONS

This application is a national phase entry under 35 U.S.C. § 371 of International Application No. PCT/CN 2024/116304, filed on Sep. 2, 2024, which claims priority to Chinese Patent Application No. 202311432802.5, filed with the China National Intellectual Property Administration on Oct. 31, 2023, and entitled “Display Panel and Display Apparatus”, the entire contents of which are incorporated herein by reference.

### TECHNICAL FIELD

The present disclosure relates to the field of display technology, and in particular to a display panel and a display apparatus.

### BACKGROUND

The Organic Light-Emitting Diode (OLED) panel has the advantages of self-luminescence, simple structure, wide viewing angle, low power consumption, and flexible display, and is one of the most promising display technologies at present.

In order to prevent screen reflection, it is required to provide a layer of polarizer on the light-emitting side of the OLED display panel. The polarizer uses the principle of polarized light to effectively reduce the reflection intensity of external ambient light on the screen. However, the thickness of the polarizer is relatively large, which is not conducive to the manufacture of a foldable and rollable screen. Increasing the transmittance of upper components of the light-emitting functional layer can effectively reduce Electroluminescence (EL) power consumption. Using a color filter on encapsulation (COE) structure instead of a polarizer structure is an effective way to improve transmittance, which can also obtain a thinner display module, reduce the difficulty of bonding, and is also conducive to further development of foldable and rollable screens. However, due to the presence of black matrix in the COE structure, external ambient light is reflected after entering the display panel, and the reflected light forms a pinhole diffraction aperture when it is emitted. Since the pixel definition layer in the display panel is arranged periodically, the cathode at the slope of the pixel definition layer forms a diffraction grating, which is prone to the occurrence of a diffraction-limited large aperture and adversely affects the display effect.

### SUMMARY

Embodiments of the present disclosure provide a display panel and a display apparatus to avoid the occurrence of a diffraction-limited large aperture and improve the display effect.

Embodiments of the present disclosure provide a display panel. The display panel includes a base substrate, a plurality of light-emitting devices, a pixel definition layer, and a light-shielding layer.

The plurality of light-emitting devices are located on a side of the base substrate and include an anode, a light-emitting functional layer, and a cathode which are stacked.

The pixel definition layer is located on a side of the cathode facing the base substrate and includes a plurality of first opening regions. The pixel definition layer includes: a first pixel definition layer, and a second pixel definition layer located on a side of the first pixel definition layer facing away from the base substrate. In a region corresponding to the first opening region, the first pixel definition layer includes a first side surface, and the second pixel definition layer includes a second side surface. The first side surface has a first angle with the plane where the base substrate is located, and the second side surface has a second angle with the plane where the base substrate is located. The first angle and the second angle are both greater than 0° and less than 90°, and the second angle is less than the first angle.

The light-shielding layer is located on a side of the light-emitting devices facing away from the base substrate and includes a plurality of second opening regions. The orthographic projection of the second opening regions on the base substrate overlaps with the orthographic projection of the first opening regions on the base substrate. The orthographic projection of the light-shielding layer on the base substrate covers at least part of the orthographic projection of the second side surface on the base substrate.

In some embodiments, the orthographic projection of the second pixel definition layer on the base substrate covers part of the orthographic projection of the first side surface on the base substrate.

In some embodiments, the display panel further includes a plurality of driving transistors between the base substrate and the light-emitting devices.

The anode includes: a first region and a second region connected to the first region at an edge of the first region. The area of the first region is larger than that of the second region.

The second region is electrically connected to the drain of the driving transistor. The orthographic projection of the first pixel definition layer on the base substrate covers the orthographic projection of the second region on the base substrate.

The orthographic projection of the first opening region on the base substrate is within the orthographic projection of the first region on the base substrate.

The second pixel definition layer includes a first portion. The orthographic projection of the first portion on the base substrate covers the orthographic projection of the second region on the base substrate.

In some embodiments, the first portion covers a part of the first side surface.

In some embodiments, the second pixel definition layer further includes a second portion located outside the first portion.

The orthographic projection of the second portion on the base substrate is within the orthographic projection of the first pixel definition layer on the base substrate.

In some embodiments, an orthographic projection of the second portion on the base substrate and an orthographic projection of the first side surface on the base substrate do not overlap with each other.

In some embodiments, the orthographic projection of the light-shielding layer on the base substrate covers the orthographic projection of the second portion on the base substrate.

In some embodiments, the distance between the orthographic projection of the second portion on the base substrate and the orthographic projection of the first side surface on the base substrate is greater than or equal to the distance between the orthographic projection of the first side surface on the base substrate and the orthographic projection of the light-shielding layer on the base substrate.

In some embodiments, the orthographic projection of the light-shielding layer on the base substrate does not overlap with a part of the orthographic projection of the first portion on the base substrate. The orthographic projection of the light-shielding layer on the base substrate is within the orthographic projection of the first pixel definition layer on the base substrate.

In some embodiments, the orthographic projection of the light-shielding layer on the base substrate covers at least part of the orthographic projection of the first side surface on the base substrate.

In some embodiments, an orthographic projection of the part of the first side surface covered by the first portion of the second pixel definition layer on the base substrate is covered by the orthographic projection of the light-shielding layer on the base substrate.

In some embodiments, a distance between an orthographic projection of the light-shielding layer on the base substrate and an orthographic projection of the first portion on the base substrate is greater than or equal to 0.

In some embodiments, the display panel includes a plurality of pixels arranged in an array. The pixels include multiple types of sub-pixels. The sub-pixels include the light-emitting devices. The second opening regions corresponding to different types of sub-pixels emit light of different colors.

In some adjacent pixels, patterns of the first portion corresponding to the same type of sub-pixels are centrosymmetric.

In some embodiments, in any adjacent four pixels in a 2×2 array, the patterns of the first portion corresponding to the same type of sub-pixels are centrosymmetric.

In some embodiments, the first pixel definition layer includes an inorganic material and the second pixel definition layer includes an organic material.

In some embodiments, in a direction perpendicular to the base substrate, a maximum thickness of the first pixel definition layer is greater than or equal to 0.5 micrometers and less than or equal to 1 micrometer.

In some embodiments, the first angle is greater than 45° and less than 75°.

In some embodiments, in a direction perpendicular to the base substrate, a maximum thickness of the first pixel definition layer is greater than or equal to 0.3 micrometers and less than or equal to 0.5 micrometers.

In some embodiments, the first angle is greater than 75°.

In some embodiments, in a direction perpendicular to the base substrate, a maximum thickness of the second pixel definition layer is greater than 0 and less than or equal to 1 micrometer.

In some embodiments, the second angle is greater than 20° and less than 30°.

Embodiments of the present disclosure provide a display apparatus, which includes the display panel provided by the embodiments of the present disclosure.

In the display panel and display apparatus provided by the embodiments of the present disclosure, the pixel definition layer includes two pixel definition layers having different side slope angles, that is, different angles between the side surfaces and the plane where the base substrate is located. The first angle of the first pixel definition layer is greater than the second angle of the second pixel definition layer, and only the cathode above the second side surface of the second pixel definition layer may form a small-angle diffraction grating. However, the orthographic projection of the light-shielding layer on the base substrate covers at least a part of the orthographic projection of the second side surface on the base substrate. Accordingly, the light-shielding layer also shields the cathode above at least a part of the second side surface, thereby blocking light reflected from the cathode above at least a part of the second side surface, alleviating or even avoiding the color separation large aperture caused by interference, and improving the display effect. In addition, the pixel definition layer is divided into two layers. The lower layer is the first pixel definition layer with a larger slope angle, which will not form a diffraction grating in this region. The upper layer has a smaller slope angle to avoid cathode breakage, ensure the continuity of the cathode, and avoid affecting the display panel production yield.

### BRIEF DESCRIPTION OF DRAWINGS

In order to more clearly illustrate the technical solutions in the embodiments of the present disclosure, the following briefly introduces the drawings required for use in the description of the embodiments. Obviously, the drawings described below are only some embodiments of the present disclosure. For ordinary technicians in this field, other drawings can be obtained based on these drawings without any creative work.

FIG. 1 is a schematic structural diagram of a display panel provided in the related art.

FIG. 2 is a schematic structural diagram of a display panel provided by an embodiment of the present disclosure.

FIG. 3 is a schematic diagram of a cross-sectional structure along line AA′ in FIG. 2 provided by an embodiment of the present disclosure.

FIG. 4 is a schematic diagram of another cross-sectional structure along line AA′ in FIG. 2 provided by an embodiment of the present disclosure.

FIG. 5 is a schematic structural diagram of another display panel provided by an embodiment of the present disclosure.

FIG. 6 is a schematic diagram of a cross-sectional structure along CC′ in FIG. 5 provided by an embodiment of the present disclosure.

FIG. 7 is a schematic structural diagram of another display panel provided by an embodiment of the present disclosure.

FIG. 8 is a schematic diagram of a cross-sectional structure along line EE′ in FIG. 7 provided by an embodiment of the present disclosure.

FIG. 9 is a schematic structural diagram of another display panel provided by an embodiment of the present disclosure.

FIG. 10 is a schematic diagram of a cross-sectional structure along line FF′ in FIG. 9 provided by an embodiment of the present disclosure.

FIG. 11 is a schematic structural diagram of another display panel provided by an embodiment of the present disclosure.

FIG. 12 is a schematic diagram of a cross-sectional structure along line JJ′ in FIG. 11 provided by an embodiment of the present disclosure.

FIG. 13 is a schematic structural diagram of another display panel provided by an embodiment of the present disclosure.

FIG. 14 is a schematic structural diagram of another display panel provided by an embodiment of the present disclosure.

FIG. 15 is a schematic structural diagram of another display panel provided by an embodiment of the present disclosure.

FIG. 16 is a schematic structural diagram of a pixel array arrangement of a display panel provided by an embodiment of the present disclosure.

FIG. 17 is a schematic structural diagram of another display panel provided by an embodiment of the present disclosure.

FIG. 18 is a schematic structural diagram of another display panel provided in an embodiment of the present disclosure.

### DETAILED DESCRIPTION

In order to make the purpose, technical solutions and advantages of the embodiments of the present disclosure more clear, the technical solutions of the embodiments of the present disclosure will be clearly and completely described below in conjunction with the drawings of the embodiments of the present disclosure. Obviously, the described embodiments are only part of the embodiments of the present disclosure, rather than all the embodiments. Furthermore, the embodiments and features in the embodiments of the present disclosure may be combined with each other without conflict. Based on the described embodiments of the present disclosure, all other embodiments obtained by ordinary technicians in this field without creative work are within the scope of protection of the present disclosure.

Unless otherwise defined, technical or scientific terms used in the present disclosure should have the same meaning as commonly understood by a person having ordinary skills in the field to which the present disclosure belongs. The terms “first,” “second,” and similar terms used in the present disclosure do not denote any order, quantity, or importance, but are only used to distinguish different components. The word “include” or “comprise” or the like mean that the elements or items preceding the word include the elements or items listed after the word and their equivalents, but not excluding other elements or items. The word “connect” or “connected” or the like is not limited to physical or mechanical connections, but may include electrical connections, whether direct or indirect.

It should be noted that the size and shape of each figure in the accompanying drawings do not reflect the actual proportion, and the purpose is only to illustrate the contents of the present disclosure. And the same or similar reference numerals throughout represent the same or similar elements or elements with the same or similar functions.

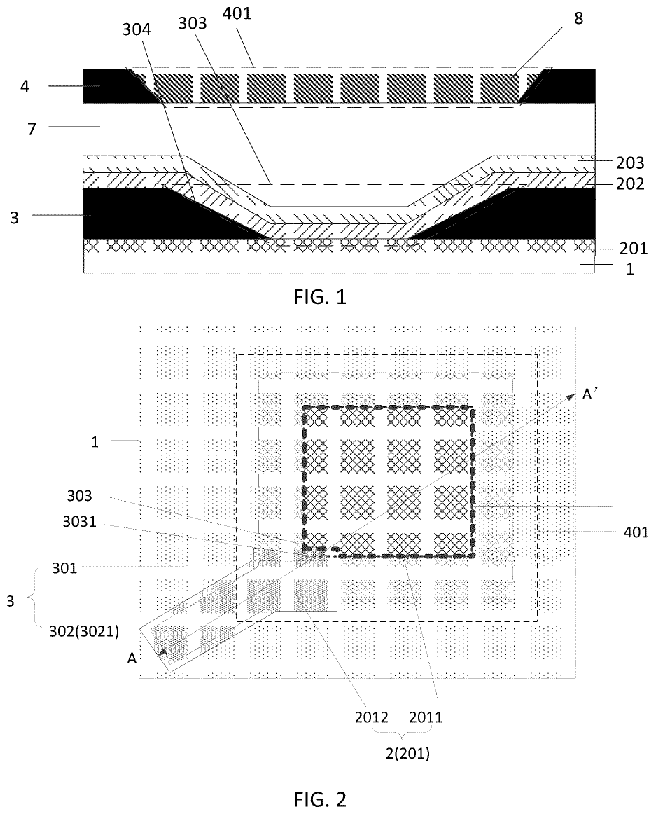

In related technology, the color filter on encapsulation (COE) structure shown in FIG. 1 includes a color conversion portion 8 and a light-shielding layer 4 located on a side of the encapsulation layer 7 facing away from the base substrate 1. The light-shielding layer 4 is provided with a second opening region 401. The color conversion portion 8 is in the second opening region 401. The orthographic projection of the second opening region 401 on the base substrate 1 covers the inclined side surfaces 304 of the pixel definition layer 3. That is, the light-shielding layer 4 does not cover the inclined side surfaces 304. When external ambient light is incident into the display panel and is reflected, the reflected light forms a pinhole diffraction aperture when it is emitted. Since the first opening region 303 of the pixel definition layer 3 in the display panel is arranged periodically, the cathode 203 on the inclined side surfaces 304 surrounding the first opening region 303 forms a diffraction grating. The diffraction grating has single-groove diffraction and inter-groove interference. There are multiple orders of principle maximum fringes in inter-groove interference at different diffraction angles. When the diffraction angle of the principle maximum fringe in the single-groove diffraction is the same as the diffraction angle of the k-th order principle maximum fringe in the inter-groove interference, a high-brightness fringe will be generated at this angle. Due to the different directions of single-groove diffraction and inter-groove interference, the central brightness is dispersed, and the external light becomes monochromatic light after passing through the color filter film, thus forming color fringes on the outer circle of the diffraction pattern, that is, a color separation large aperture. Furthermore, the slope angle of the inclined side surface 304 is usually small, and a large aperture is formed after light is emitted at the principal maxima from an edge of the slope of the pixel definition layer. The diffraction-limited large aperture adversely affects the display effect of the display panel.

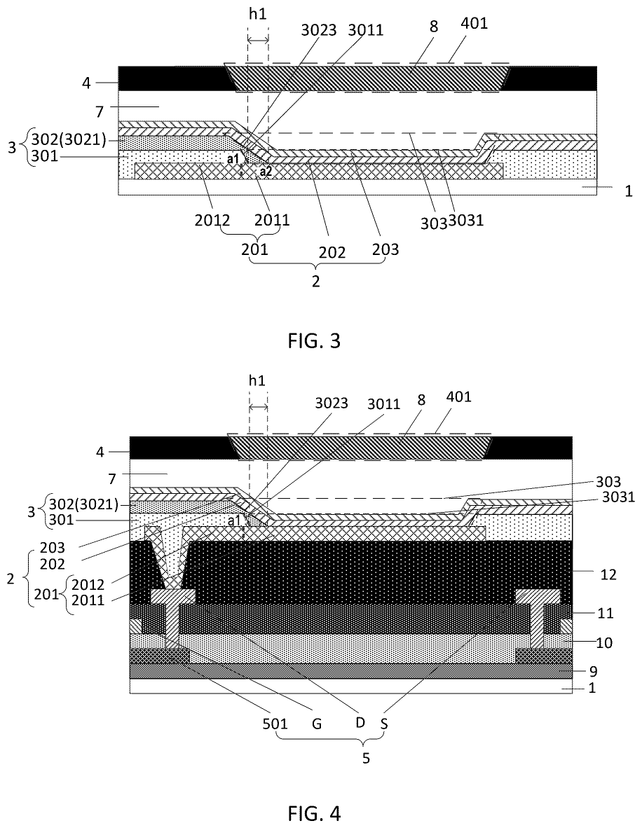

Embodiments of the present disclosure provide a display panel as shown in FIG. 2 and FIG. 3. The display panel includes a base substrate 1, a plurality of light-emitting devices 2, a pixel definition layer 3, and a light-shielding layer 4.

The light-emitting devices 2 are located on a side of the base substrate 1 and include an anode 201, a light-emitting functional layer 202, and a cathode 203 which are stacked.

The pixel definition layer 3 is located on a side of the cathode 203 facing the base substrate 1 and includes a plurality of first opening regions 303. The pixel definition layer 3 includes: a first pixel definition layer 301 and a second pixel definition layer 302 located on a side of the first pixel definition layer 301 facing away from the base substrate 1. In a region corresponding to the first opening region 303, the first pixel definition layer 301 includes a first side surface 3011, and the second pixel definition layer 302 includes a second side surface 3023. The first side surface 3011 forms a first angle a1 with the plane where the base substrate 1 is located, and the second side surface 3023 forms a second angle a2 with the plane where the base substrate 1 is located. The first angle a1 and the second angle a2 are both greater than 0° and less than 90°, and the second angle a2 is less than the first angle a1.

The light-shielding layer 4 is located on a side of the light-emitting device 2 facing away from the base substrate 1 and includes a plurality of second opening regions 401. The orthographic projection of the second opening region 401 on the base substrate 1 overlaps with the orthographic projection of the first opening region 303 on the base substrate 1. The orthographic projection of the light-shielding layer 4 on the base substrate 1 covers at least a part of the orthographic projection of the second side surface 3023 on the base substrate 1.

It should be noted that in the related art, cathodes of the plurality of light-emitting devices are arranged on the entire surface and connected as a one-piece cathode, so that the light-emitting devices can be lit by providing a signal to the cathode arranged on the entire surface and corresponding signals to the anodes of the plurality of light-emitting devices. If the display panel includes a single-layer pixel definition layer, the inclination angle of the side surface of the single-layer pixel definition layer is increased to avoid interference between light rays reflected by the diffraction gratings. Since the thickness of the single-layer pixel definition layer is relatively thick, the inclination angle of the side surface (that is, the angle between the side surface and the plane where the base substrate is located) being too large will cause the cathode to break on the side surface of the pixel definition layer, that is, it is impossible to form a continuous cathode on the entire surface, resulting in the light-emitting devices being unable to be lit, affecting the display panel production yield.

In the display panel provided by embodiments of the present disclosure, the pixel definition layer includes two pixel definition layers having different slope angles, i.e., angles between the side surfaces and the plane where the base substrate is located. The two pixel definition layers are distributed as a first pixel definition layer and a second pixel definition layer located on the side of the first pixel definition layer facing away from the base substrate. The first angle of the first pixel definition layer is greater than the second angle of the second pixel definition layer. Only the cathode above the second side surface of the second pixel definition layer forms a small-angle diffraction grating. However, the orthographic projection of the light-shielding layer on the base substrate covers at least a part of the orthographic projection of the second side surface on the base substrate. Accordingly, the light-shielding layer also shields at least a part of the cathode above the second side surface, thereby blocking at least a part of the light reflected by the cathode above the second side surface, alleviating or even avoiding the color separation large aperture caused by interference, and improving the display effect. In addition, the pixel definition layer is divided into two layers. The lower layer is the first pixel definition layer with a larger slope angle, which will not form a diffraction grating at this region. The upper layer has a smaller slope angle to avoid cathode breakage, ensure the continuity of the cathode, and avoid affecting the display panel production yield.

It should be noted that FIG. 2 is a schematic diagram of the orthographic projection of some film layers on the base substrate 1 in the display panel, and FIG. 3 is a cross-sectional view along AA′ in FIG. 2.

In some embodiments, as shown in FIG. 3, the second pixel definition layer 302 covers at least a part of the first side surface 3011. That is, at least a part of the cathode covers a part of the second side surface but does not cover the first side surface, thereby further preventing the cathode from breaking in the region corresponding to the first side surface, ensuring the continuity of the cathode and avoiding affecting the display panel production yield.

In some embodiments, the display panel includes a plurality of pixels arranged in an array. Each pixel includes multiple types of sub-pixels. Each sub-pixel includes a light-emitting device. The light-emitting colors of the second opening regions corresponding to different sub-pixels are different.

In some embodiments, as shown in FIG. 2 and FIG. 3, the first pixel definition layer 301 includes a first sub-opening region 3031.

In some embodiments, the first opening region corresponds to the light-emitting region of the sub-pixel. In implementations, a first pixel definition layer is formed first, and a patterning process is performed on the first pixel definition layer to form a first sub-opening region to preliminarily define the light-emitting region of the sub-pixel. The orthographic projection of the first sub-opening region on the base substrate is within the orthographic projection of the anode on the base substrate. Then, a pattern of a second pixel definition layer is formed. The first opening region of the pixel definition layer, i.e., the light-emitting region of the sub-pixel, is jointly determined by the first pixel definition layer and the second pixel definition layer. That is, the region surrounded by part of the first side surface and part of the second side surface is the first opening region.

In some embodiments, the first angle is greater than 45° and less than 90°. This can avoid the occurrence of a diffraction-limited large aperture caused by a small slope angle of the first side surface.

In some embodiments, the second angle is greater than 20° and less than 30°. This can prevent the cathode from breaking on the pixel definition layer.

In some embodiments, the thickness of the first pixel definition layer is greater than the thickness of the anode.

In some embodiments, the thickness of the anode is greater than or equal to 0.1 micrometer and less than or equal to 0.15 micrometer. In a direction perpendicular to the base substrate, the maximum thickness of the first pixel definition layer is greater than or equal to 0.5 micrometer and less than or equal to 1 micrometer. The first angle is greater than 45° and less than 75°.

Alternatively, in some embodiments, in a direction perpendicular to the base substrate, the maximum thickness of the first pixel definition layer is greater than or equal to 0.3 micrometers and less than or equal to 0.5 micrometers. The first angle is greater than 75°.

In some embodiments, the light-emitting functional layer includes: an organic light-emitting layer, and a common layer located between the organic light-emitting layer and the cathode and/or between the organic light-emitting layer and the anode. The common layer includes, for example, an electron transport layer, a hole transport layer, an electron injection layer, a hole injection layer, an electron blocking layer, a hole blocking layer, etc. For example, the common layers corresponding to the plurality of sub-pixels may be made of the same material. When the first angle is greater than 75°, that is, the slope angle of the first side surface is larger, the common layer in the light-emitting functional layer is broken at the first side surface, which can avoid crosstalk between adjacent sub-pixels and improve the display effect.

In some embodiments, in a direction perpendicular to the base substrate, a maximum thickness of the second pixel definition layer is greater than 0 and less than or equal to 1 micrometer.

In some embodiments, as shown in FIG. 3, the display panel further includes: an encapsulation layer 7 located between the light-shielding layer 4 and the cathode 203, and a color conversion portion 8 located at least within the second opening region 401. The light-shielding layer 4 and the color conversion portion 8 form a COE structure.

It should be noted that, in the related art, a polarizer needs to be provided on the light-emitting side of the display panel to prevent screen reflection. The polarizer uses the principle of polarized light to effectively reduce the reflection intensity of external ambient light on the screen. However, the thickness of polarizer is relatively large, which is not conducive to the manufacture of a foldable and rollable screen, and will also cause the transmittance of display product to decrease, affecting power consumption.

The display panel provided by the embodiments of the present disclosure reduces the reflection of the display panel by providing a COE structure instead of a polarizer. The thickness of the COE structure is usually less than that of the polarizer, thereby reducing the total thickness of the display panel, making the display panel more conducive to be applied in foldable and rollable display products, and also helping to improve the light transmittance of the display panel and reduce the power consumption of the display panel. Furthermore, since the thickness of the display panel is reduced, when the display panel is applied in a 3D display product, it is also helpful to reduce the difficulty of laminating the display panel with other components in the 3D display product.

In some embodiments, the multiple types of sub-pixels included in each pixel include: a red sub-pixel, a blue sub-pixel, and a green sub-pixel.

In some embodiments of the present disclosure, the light-emitting device may be at least one of an organic light-emitting diode (OLED), a quantum dot light-emitting diode (QLED), a Micro LED, or a Mini LED. Next, the display panel provided by embodiments of the present disclosure is introduced by taking the light-emitting device as an OLED as an example.

In some embodiments, the light-emitting functional layer in the red sub-pixel is a red light-emitting functional layer, the light-emitting functional layer in the blue sub-pixel is a blue light-emitting functional layer, and the light-emitting functional layer in the green sub-pixel is a green light-emitting functional layer.

Accordingly, in some embodiments, the color conversion portion corresponding to the red sub-pixel is a red color conversion portion, the color conversion portion corresponding to the blue sub-pixel is a blue color conversion portion, and the color conversion portion corresponding to the green sub-pixel is a green color conversion portion.

In implementations, a color conversion portion with a light-emitting color same as that of a light-emitting region is provided in the light-emitting region of the light-emitting device, thereby improving the color purity.

Alternatively, in some embodiments, every sub-pixel includes a blue light-emitting device. That is, the light-emitting functional layer in each sub-pixel is a blue light-emitting functional layer.

In some embodiments, the color conversion portion corresponding to the red sub-pixel is a red color conversion portion, and the color conversion portion corresponding to the green sub-pixel is a green color conversion portion.

For example, the red color conversion portion is used to absorb blue light and emit red light, and the green color conversion portion is used to absorb blue light and emit green light.

In some embodiments, since the three primary colors of red, green and blue are used to achieve light emission, and the light-emitting devices are blue light-emitting devices, there is no need to set a blue color conversion portion at the corresponding position of the blue quantum dot color film. That is, the second opening region corresponding to the blue sub-pixel does not include a color conversion portion, but includes a light-transmitting filling portion. For example, the light-transmitting filling portion can be filled with scattering particles, so that the scattering particles can play a role in improving the luminous viewing angle.

Alternatively, in implementations, the second opening region corresponding to the blue sub-pixel may also include a blue color conversion portion, and the blue color conversion portion is used to improve the color purity of the blue sub-pixel.

In implementations, the color conversion portion is, for example, a quantum dot color film. That is, the red color conversion portion is a red light quantum dot color film, the green color conversion portion is a green light quantum dot color film, and the blue color conversion portion is a blue light quantum dot color film.

In some embodiments, the encapsulation layer may be, for example, Thin-Film Encapsulation (TFE).

In some embodiments, the encapsulation layer includes a first inorganic encapsulation sub-layer/an organic encapsulation sub-layer/a second inorganic encapsulation sub-layer in a stacked manner.

In some embodiments, the material of the first inorganic encapsulation sub-layer includes at least one of SiN or SiON. The material of the organic encapsulation sub-layer includes at least one of resin or polyimide. The material of the second inorganic encapsulation sub-layer includes at least one of SiN or SiON.

In some embodiments, an area of an orthographic projection of the second opening region on the base substrate is larger than that of an orthographic projection of the first opening region on the base substrate. In this way, the light-shielding layer can be prevented from affecting the sub-pixel aperture ratio.

Accordingly, in some embodiments, as shown in FIG. 3, the orthographic projection of the light-shielding layer 4 on the base substrate 1 and the orthographic projection of at least a part of the first side surface 3011 on the base substrate 1 do not overlap with each other. That is, at least a part of the first side surface is not covered by the light-shielding layer.

In some embodiments, the first pixel definition layer includes an inorganic material and the second pixel definition layer includes an organic material.

In implementations, the inorganic material included in the first pixel definition layer is, for example, at least one of the following: silicon nitride (SiNₓ), silicon oxide (SiOₓ), and silicon oxynitride (SiON). That is, the first pixel definition layer has a higher transmittance and a lower reflectivity, which is beneficial to reducing light reflection on the first side surface. Even if at least a part of the first side surface is not covered by the light-shielding layer, it is possible to avoid the formation of a diffraction grating at the first side surface to affect the display effect.

In implementations, the second pixel definition layer includes an organic material to which a black dye is added. That is, the second pixel definition layer is a light-shielding pixel definition layer with low transmittance and high reflectivity. Thus, the metal layer below the pixel definition layer can be shielded, thereby preventing the metal layer below the pixel definition layer from reflecting light and affecting the display effect.

In implementations, the second pixel definition layer includes, for example, polyimide added with black dye.

In some embodiments, the material of the light-shielding layer is the same as the material of the second pixel definition layer. That is, the material of the light-shielding layer includes, for example, polyimide added with black dye.

In some embodiments, as shown in FIG. 4, the display panel further includes: a plurality of driving transistors 5 located between the base substrate 1 and the light-emitting device 2.

The driving transistor includes: a source electrode S and a drain electrode D arranged in the same layer, an active layer 501, and a gate electrode G located between the active layer 501 and the source electrode S. The display panel further includes: a buffer layer 9 located between the base substrate 1 and the active layer 501, a gate insulation layer 10 located between the active layer 501 and the gate electrode G, an interlayer insulation layer 11 located between the gate electrode G and the source electrode S and drain electrode D, and a planarization layer 12 located between the source electrode S and drain electrode D and the anode 201.

In some embodiments, the driving transistor is a thin film transistor. In implementations, the display panel includes pixel driving circuits corresponding to the sub-pixels one by one. In addition to the driving transistors, the pixel driving circuits may include more thin film transistors and capacitors.

In implementations, a plurality of signal lines are provided on the base substrate. The plurality of signal lines include a plurality of gate lines, a plurality of data lines, a plurality of initialization signal lines, a plurality of power lines, and the like. For example, the pixel driving circuits of a row of sub-pixels are connected to one gate line. The pixel driving circuits of a column of sub-pixels are connected to one data line. The pixel driving circuits of a column of sub-pixels are connected to one initialization signal line. The pixel driving circuits of a column of sub-pixels are connected to one power signal line. In this way, corresponding signals can be input to the pixel driving circuits through these signal lines to control the pixel driving circuits to drive the light-emitting devices to emit light. The specific structure and working principle can be the same as those in the prior art and will not be described in detail here.

In some embodiments, the source electrode, the drain electrode, and the gate electrode comprise metal materials.

In some embodiments, the active layer includes a semiconductor material. In implementations, the active layer further includes a source region and a drain region. The source region is electrically connected to the source electrode, and the drain region is electrically connected to the drain electrode.

In some embodiments, the active layer can be made of amorphous silicon, polycrystalline silicon, oxide semiconductor materials, etc. It should be noted that the source region and the drain region mentioned above may be conductive regions formed by doping the active layer with n-type impurities or p-type impurities.

In some embodiments, the display panel is a rigid display panel. Correspondingly, the base substrate is a rigid base substrate, such as a glass base substrate or a plastic base substrate.

Alternatively, in some embodiments, the display panel is a flexible display panel. The base substrate may be a flexible base substrate, such as a polyimide base substrate.

It should be noted that FIG. 4 is illustrated by taking a top-gate thin film transistor as an example of a driving transistor, that is, the gate is located on the side of the active layer facing away from the base substrate. In implementations, the thin film transistor may also be a bottom-gate structure, that is, the gate is located between the active layer and the buffer layer.

In some embodiments, as shown in FIG. 4, the anode 201 includes: a first region 2011 and a second region 2012 connected to an edge of the first region 2011. The area of the first region 2011 is larger than the area of the second region 2012. The surface of the first region 2011 facing away from the base substrate 1 is a plane.

The second region 2012 is electrically connected to the drain electrode D of the driving transistor 5. The orthographic projection of the first pixel definition layer 301 on the base substrate 1 covers the orthographic projection of the second region 2012 on the base substrate 1.

The orthographic projection of the first opening region 303 on the base substrate 1 is within the orthographic projection of the first region 2011 on the base substrate 1.

The second pixel definition layer 302 includes a first portion 3021. The orthographic projection of the first portion 3021 on the base substrate 1 covers the orthographic projection of the second region 2012 on the base substrate 1.

In implementations, as shown in FIG. 4, the anode 201 is electrically connected to the drain electrode D through a via hole penetrating the planarization layer 12.

In implementations, since the second region of the anode needs to be electrically connected to the drain electrode through a via hole penetrating the planarization layer, and the thickness of the anode is smaller than the depth of the via hole, a groove region is formed on the surface of the anode facing away from the base substrate at the via hole. That is, the surface of the anode is uneven in the region where the anode is electrically connected to the drain electrode. That is, the second region of the anode is a region whose surface on the side facing away from the base substrate is not completely flat, while the first region of the anode is a region whose surface on the side facing away from the base substrate is flat and has a good flattening effect. The first opening region exposes a part of the first region of the anode, and the orthographic projection of the first opening region on the base substrate does not overlap with the orthographic projection of the second region of the anode on the base substrate. That is, the first region of the anode with good surface flatness corresponds to the light-emitting region of the sub-pixel, which is beneficial to improving the display effect.

In the display panel provided by embodiments of the present disclosure, since the first pixel definition layer is an inorganic pixel definition layer with high transmittance, reflecting light leakage cannot be completely avoided by simply shielding the region where the anode and the drain are electrically connected by the first pixel definition layer. The orthographic projection of the first portion of the second pixel definition layer on the base substrate covers the orthographic projection of the second region on the base substrate. Since the second pixel definition layer is a light-shielding pixel definition layer, the first portion of the second pixel definition layer can block the region where the anode and the drain are electrically connected, avoiding reflected light leakage in this region, thereby improving the display effect.

In some embodiments, as shown in FIG. 4, the first portion 3021 covers a part of the first side surface 3011.

In some embodiments, as shown in FIG. 4, a distance h1 between a bottom edge of the second side surface 3023 of the first portion 3021 and a bottom edge of the first side surface 3011 is greater than 0.

In implementations, considering the angles of the first side surface and the second side surface and avoiding affecting the sub-pixel aperture ratio, h1 is greater than or equal to 2 micrometers and less than or equal to 4 micrometers.

For example, the first portion 3021 covers the first side surface 3011 near the connection between the second region 2012 and the first region 2011.

It should be noted that as long as a first portion covering part of the first side surface is provided at each first opening region, even if the cathode breaks at another part of the first side surface not covered by the second pixel definition layer, the cathode will not break in the region corresponding to the first portion, thereby ensuring the continuity of the entire surface of the cathode and avoiding affecting the display panel production yield.

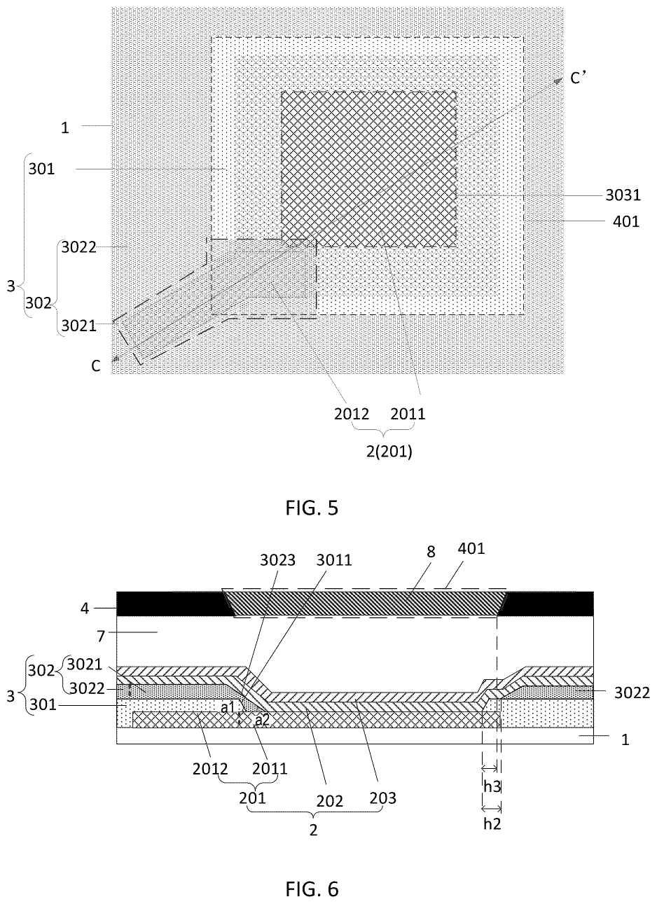

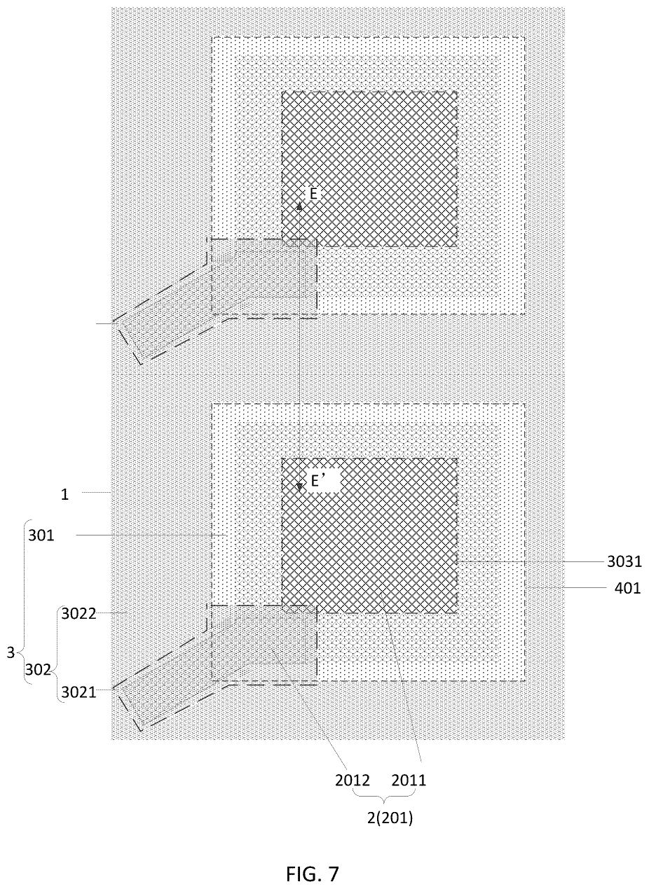

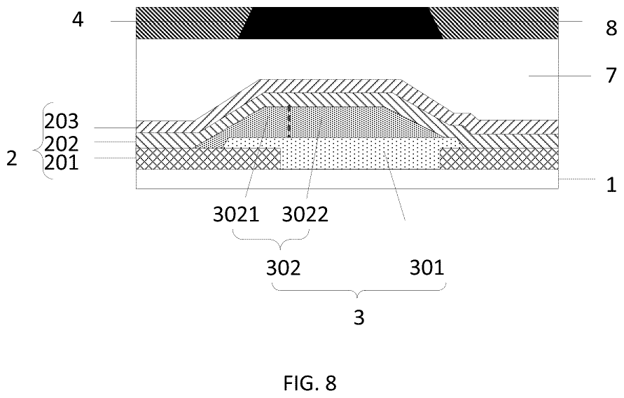

In some embodiments, as shown in FIG. 5, FIG. 6, FIG. 7, and FIG. 8, the second pixel definition layer 302 further includes a second portion 3022 located outside the first portion 3021.

The orthographic projection of the second portion 3022 on the base substrate 1 is within the orthographic projection of the first pixel definition layer 301 on the base substrate 1.

In the display panel provided by embodiments of the present disclosure, the second pixel definition layer further includes a second portion, so that the region except the region where the anode and the drain are electrically connected can be shielded by the second portion to avoid reflection from other metal material film layers.

In implementations, in the first opening region, both the first portion and the second portion include a second side surface. The first portion and the second portion of the second pixel definition layer are integrally connected. That is, the first portion and the second portion of the second pixel definition layer are formed in the same patterning process. The portion of the second pixel definition layer whose orthographic projection covers the region where the anode and the drain are electrically connected is the first portion, and the remaining portion is the second portion. In order to reduce the difficulty of preparing the second pixel definition layer, the second angle corresponding to the second side surface of the first portion is equal to the second angle corresponding to the second side surface of the second portion.

It should be noted that FIG. 6 is a cross-sectional view along CC′ in FIG. 5. FIG. 8 is a cross-sectional view along EE′ in FIG. 7. FIG. 6 and FIG. 8 do not show film layers such as the driving transistor.

In some embodiments, as shown in FIG. 6, the orthographic projection of the second portion 3022 on the base substrate 1 and the orthographic projection of the first side surface 3011 on the base substrate 1 do not overlap with each other.

That is, the second portion does not cover the first side surface.

In some embodiments, as shown in FIG. 6, the orthographic projection of the light-shielding layer 4 on the base substrate 1 covers the orthographic projection of the second portion 3022 on the base substrate 1.

In the display panel provided by embodiments of the present disclosure, the orthographic projection of the light-shielding layer on the base substrate covers the orthographic projection of the second portion on the base substrate, thereby blocking the second side surface of the second portion through the light-shielding layer. The light-shielding layer also blocks the cathode above the second side surface of the second portion, thereby blocking the light reflected from the cathode above the second side surface of the second portion, alleviating or even avoiding the color separation large aperture caused by interference, and improving the display effect of the display apparatus.

In some embodiments, as shown in FIG. 6, the distance h2 between the orthographic projection of the second portion 3022 on the base substrate 1 and the orthographic projection of the first side surface 3011 on the base substrate 1 is greater than or equal to the distance h3 between the orthographic projection of the first side surface 3011 on the base substrate 1 and the orthographic projection of the light-shielding layer 4 on the base substrate 1.

It should be noted that, in FIG. 6, the distance h2 between the orthographic projection of the second portion 3022 on the base substrate 1 and the orthographic projection of the first side surface 3011 on the base substrate 1 greater than the distance h3 between the orthographic projection of the first side surface 3011 on the base substrate 1 and the orthographic projection of the light-shielding layer 4 on the base substrate 1 is used as an example to illustrate. In implementations, the distance h2 between the orthographic projection of the second portion 3022 on the base substrate 1 and the orthographic projection of the first side surface 3011 on the base substrate 1 being equal to the distance h3 between the orthographic projection of the first side surface 3011 on the base substrate 1 and the orthographic projection of the light-shielding layer 4 on the base substrate 1 can also block the light reflected from the cathode above the second side surface of the second portion, alleviate or even avoid the color separation large aperture caused by interference, and improve the display effect of the display apparatus.

In some embodiments, a distance h3 between an orthographic projection of the first side surface 3011 on the base substrate 1 and an orthographic projection of the light-shielding layer 4 on the base substrate 1 is greater than or equal to 4 micrometers. Correspondingly, a distance h2 between the orthographic projection of the second portion 3022 on the base substrate 1 and the orthographic projection of the first side surface 3011 on the base substrate 1 is greater than or equal to 4 micrometers.

In some embodiments, as shown in FIGS. 2 to 6, the orthographic projection of the light-shielding layer 4 on the base substrate 1 and part of the orthographic projection of the first portion 3021 on the base substrate 1 have an overlapped region. The orthographic projection of the light-shielding layer 4 on the base substrate 1 does not overlap with the remaining part of the orthographic projection of the first portion 3021 on the base substrate 1. The orthographic projection of the light-shielding layer 4 on the base substrate 1 is within the orthographic projection of the first pixel definition layer 301 on the base substrate 1.

That is, the light-shielding layer does not completely cover the first portion of the second pixel definition layer, to ensure that the orthographic projection of the light-shielding layer on the base substrate falls within the orthographic projection of the first pixel definition layer on the base substrate, thereby preventing the light-shielding layer from affecting the sub-pixel aperture ratio.

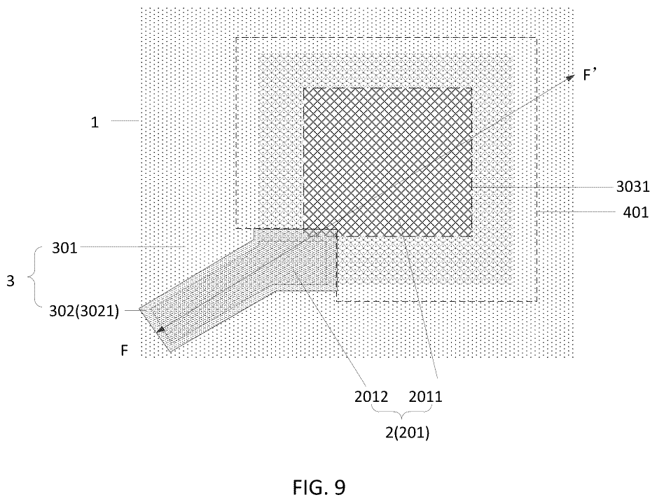

Alternatively, in some embodiments, as shown in FIG. 9 to FIG. 12, the orthographic projection of the light-shielding layer 4 on the base substrate 1 covers part of the orthographic projection of the first side surface 3011 on the base substrate 1. For example, the orthographic projection of the first side surface 3011 covered by the first portion 3021 of the second pixel definition layer 302 on the base substrate 1 is covered by the orthographic projection of the light-shielding layer 4 on the base substrate 1.

In the display panel provided by embodiments of the present disclosure, the first side surface covered by the first portion is shielded by the light-shielding layer. Correspondingly, the second side surface of the first portion above the first side surface is also shielded by the light-shielding layer. Compared with the case where the orthographic projection of the light-shielding layer on the base substrate does not cover the orthographic projection of the first side surface on the base substrate, the light-shielding layer shields more portions of the second side surface of the first portion, and then the light-shielding layer blocks more light reflected from the cathode arranged above the second side surface, further avoiding the occurrence of color separation large aperture caused by interference, and improving the display effect.

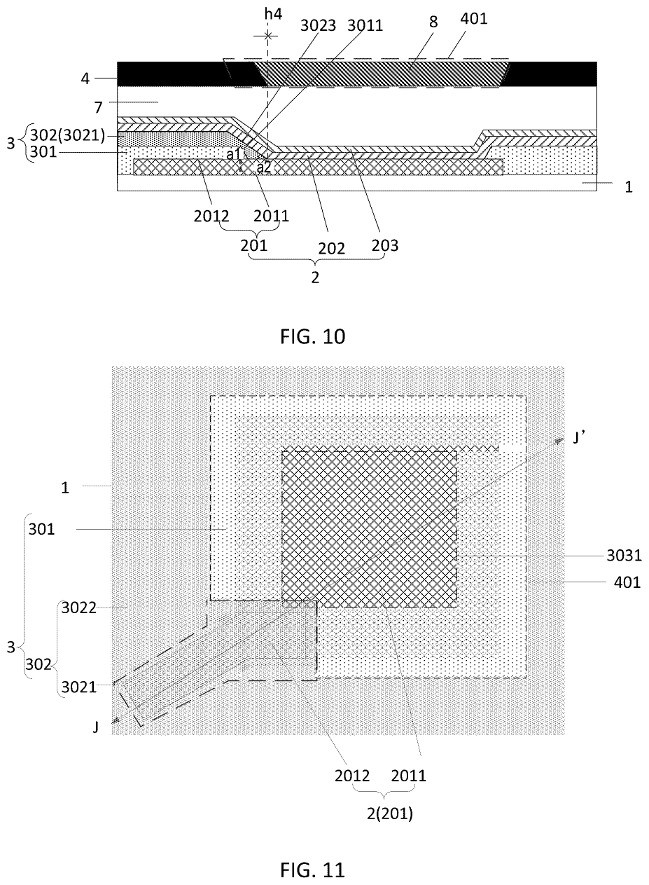

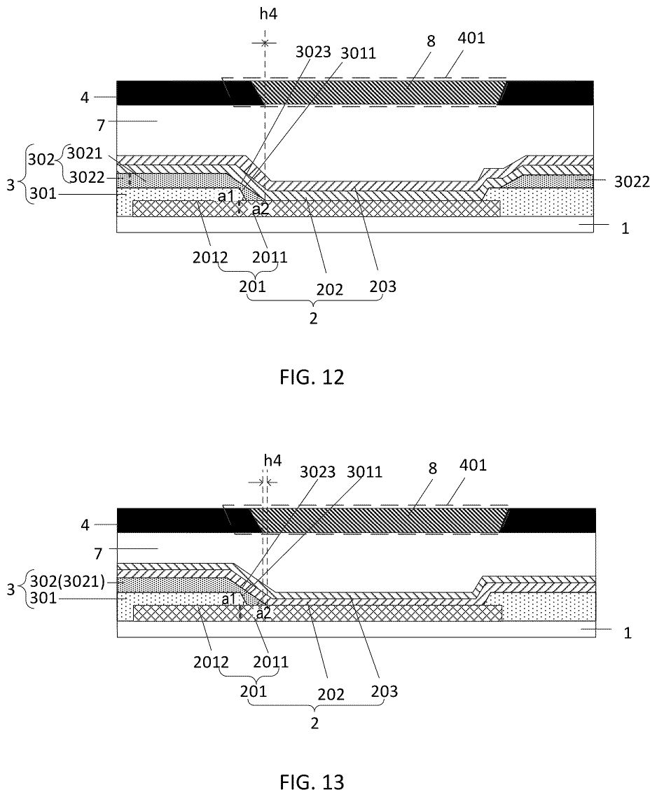

It should be noted that FIG. 10 is a cross-sectional view along FF′ in FIG. 9. FIG. 12 is a cross-sectional view along JJ′ in FIG. 11. In FIGS. 9 and 10, the second pixel definition layer 302 only includes the first portion 3021 but does not include the second portion 3022. In FIGS. 11 and 12, the second pixel definition layer 302 includes the first portion 3021 and the second portion 3022.

In some embodiments, as shown in FIGS. 9 to 12, 13, and 14, in the region where the orthographic projection of the light-shielding layer 4 on the base substrate 1 covers part of the orthographic projection of the first side surface 3011 on the base substrate 1, the distance between the orthographic projection of the light-shielding layer 4 on the base substrate 1 and the orthographic projection of the first side surface 3011 on the base substrate 1 is less than or equal to the distance between the orthographic projection of the first portion 3021 on the base substrate 1 and the orthographic projection of the first side surface 3011 on the base substrate 1. That is, the light-shielding layer 4 is retracted relative to the first portion 3021 toward the side away from the second opening region. The edge of the light-shielding layer 4 does not exceed the edge of the second side surface 3023 of the first portion 3021, thereby preventing the light-shielding layer from affecting the sub-pixel aperture ratio while shielding the second side surface as much as possible.

In some embodiments, as shown in FIGS. 9 to 12, 13, and 14, the distance between the orthographic projection of the light-shielding layer 4 on the base substrate 1 and the orthographic projection of the first portion 3021 on the base substrate 1 is greater than or equal to 0. For example, as shown in FIGS. 10, 12, 13, and 14, a distance h4 between the bottom edge of the second side surface 3023 of the first portion 3021 and the bottom edge of the inclined surface of the light-shielding layer 4 is greater than or equal to 0.

In some embodiments, as shown in FIGS. 9 to 12, the orthographic projection of the light-shielding layer 4 on the base substrate 1 covers the orthographic projection of the second pixel definition layer 302 on the base substrate 1. The distance h4 between the bottom edge of the second side surface 3023 of the first portion 3021 and the bottom edge of the inclined surface of the light-shielding layer 4 is equal to 0.

For example, in FIGS. 9 and 10, the orthographic projection of the light-shielding layer 4 on the base substrate 1 covers the orthographic projection of the second side surface 3023 of the first portion 3021 on the base substrate 1. In FIGS. 11 and 12, the orthographic projection of the light-shielding layer 4 on the base substrate 1 covers the second side surface 3023 of the first portion 3021 and the orthographic projection of the second side surface 3023 of the second portion 3022 on the base substrate 1.

That is, in embodiments of the present disclosure, an orthographic projection of the light-shielding layer on the base substrate covers an orthographic projection of all the second side surfaces of the second pixel definition layer on the base substrate. The light-shielding layer blocks the light reflected from the cathode arranged above all the second side surfaces, avoiding the color separation large aperture caused by interference, thereby improving the display effect.

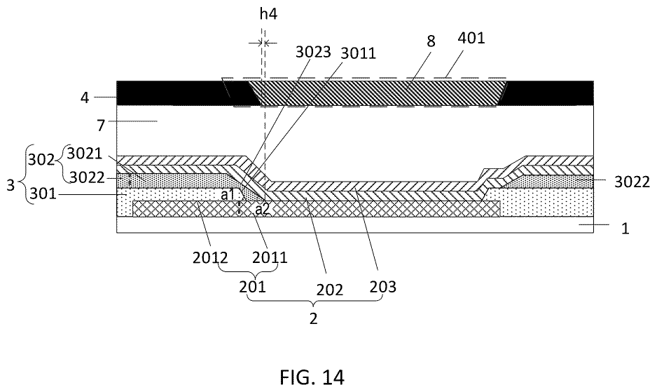

Alternatively, as shown in FIGS. 13 and 14, the orthographic projection of the light-shielding layer 4 on the base substrate 1 covers part of the orthographic projection of the first side surface 3011 on the base substrate 1. The orthographic projection of the light-shielding layer 4 on the base substrate 1 also covers part of the orthographic projection of the second side surface 3023 of the first portion 3021 on the base substrate 1. The distance h4 between the bottom edge of the second side surface 3023 of the first portion 3021 and the bottom edge of the inclined surface of the light-shielding layer 4 is greater than 0.

In some embodiments, as shown in FIGS. 10, 12, 13, and 14, the distance h4 between the bottom edge of the second side surface 3023 of the first portion 3021 and the bottom edge of the inclined surface of the light-shielding layer 4 is greater than or equal to 0 and less than or equal to 1 micrometer.

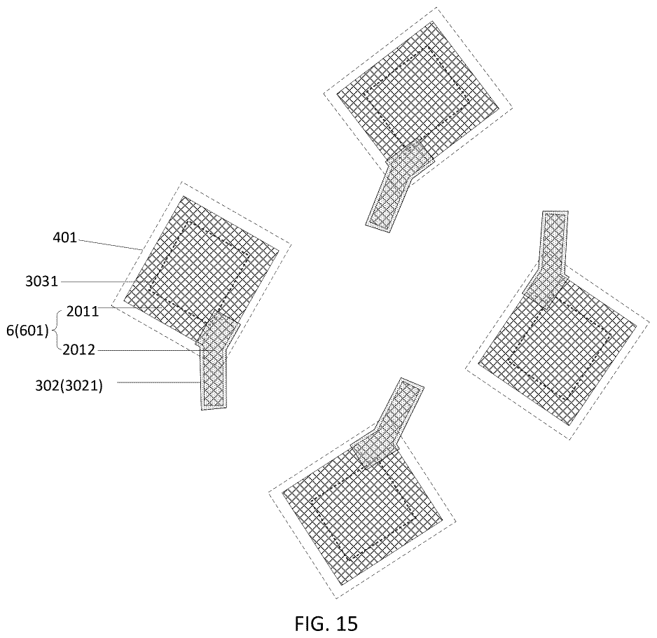

In some embodiments, as shown in FIG. 15, in some adjacent pixels 6, the patterns of the first portions 3021 corresponding to the same type of sub-pixels 601 are centrosymmetric.

In this way, in at least some adjacent pixels, the first portions of the same type of sub-pixels are concentrated near the symmetry center. Even if a diffraction grating is formed on the cathode corresponding to the second side surface of the first portion, when the diffraction angle of the principle maximum fringe in the single-groove diffraction is the same as the diffraction angle of the k-th order principle maximum fringe in the inter-groove interference to generate high-brightness fringes, the high-brightness fringes corresponding to each type of sub-pixels can be mixed into white light. That is to say, even if diffraction occurs, the appearance of monochrome high-brightness fringe can be avoided, further alleviating or even avoiding the color separation large aperture caused by interference, and improving the display effect.

In some embodiments, as shown in FIG. 15, in any adjacent four pixels 6 of a 2×2 array, the patterns of the first portions 3021 corresponding to the same type of sub-pixels 601 are centrosymmetric.

In this way, the first portions of the same type of sub-pixels in more adjacent pixels are concentrated near the symmetry center. Even if a diffraction grating is formed on the cathode corresponding to the second side surface of the first portion, when the diffraction angle of the principle maximum fringe in the single-groove diffraction is the same as the diffraction angle of the k-th order principle maximum fringe in the inter-groove interference to generate high-brightness fringes, the high-brightness fringes corresponding to each type of sub-pixel can be mixed into white light. That is to say, even if diffraction occurs, the appearance of monochrome high-brightness fringe can be avoided, further alleviating or even avoiding the color separation large aperture caused by interference, and improving the display effect.

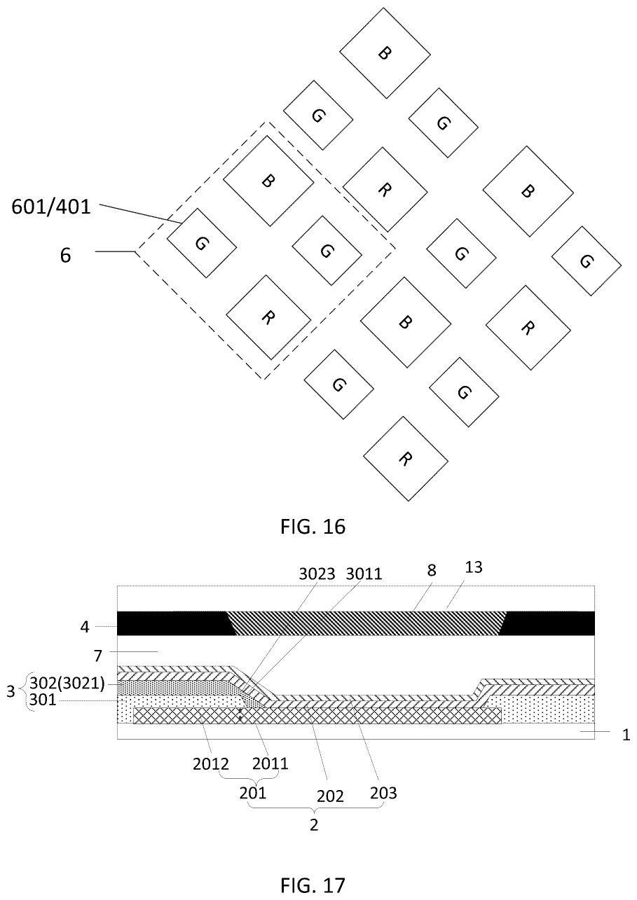

It should be noted that FIG. 15 only shows one type of sub-pixel 601 in the pixel 6. In implementations, the pixels 6 arranged in an array are shown in FIG. 16, for example. Each pixel 6 includes four sub-pixels 601. The four sub-pixels 601 include one blue sub-pixel B, one red sub-pixel R, and two green sub-pixels G. The pixel arrangement shown in FIG. 16 is called a diamond pixel. The region of the sub-pixel 601 shown in FIG. 16 is the second opening region 401 corresponding to the sub-pixel 601. The four sub-pixels 601 are arranged in a diamond shape. The area of the second opening region 401 corresponding to the red sub-pixel R is smaller than that of the second opening region 401 corresponding to the blue sub-pixel B, and the area of the second opening region 401 corresponding to the green sub-pixel G is smaller than that of the second opening region 401 corresponding to the red sub-pixel R.

Alternatively, in implementations, pixels can also be arranged in other ways. As long as four sub-pixels of the same type as a group are arranged periodically so that the patterns of the first portions of the group of sub-pixels of the same type are centrosymmetric, it is possible to alleviate or even avoid the appearance of a large monochromatic aperture with higher brightness, that is, to alleviate or even avoid the appearance of a color separation large aperture caused by interference, thereby improving the display effect.

In implementations, the number of sub-pixels included in a pixel can be selected according to actual pixel arrangement requirements. A pixel can include 2, 3 or more sub-pixels. The sub-pixels can be arranged in one row or multiple rows, and the sub-pixels in multiple rows can be arranged in a staggered or non-misaligned manner. The sub-pixels can also be arranged in one column or multiple columns, and the sub-pixels in multiple columns can be arranged in a staggered or non-misaligned manner. In implementations, the shape of the sub-pixel opening region, i.e., the first opening region, can also be set as required. In FIGS. 2, 5, 7, 9 and 11, the orthographic projection of the first sub-opening region 3031 on the base substrate 1 is a rectangular shape as an example for illustration. Correspondingly, the first opening region is a rectangular shape with one corner retracted. The second opening region in FIGS. 2, 5, 7, and 16 is a rectangular shape. The second opening region in FIGS. 9 and 11 is a rectangular shape with one corner retracted. Alternatively, in implementations, the shape of the orthographic projection of the first sub-opening region on the base substrate can also be other shapes such as a circle, an ellipse, a pentagon, or a hexagon. Correspondingly, the shape of the orthographic projection of the first opening region on the base substrate can be other shapes such as an approximate circle, an approximate ellipse, an approximate pentagon, or an approximate hexagon. The shape of the second opening region can be other shapes such as a circle, an ellipse, a pentagon, or a hexagon. Or, the shape of the orthographic projection of the second opening region on the base substrate can also be other shapes such as an approximate circle, an approximate ellipse, an approximate pentagon, or an approximate hexagon.

In some embodiments, as shown in FIG. 17, the display panel further includes a protective layer 13 covering the color conversion portion 8 and the light-shielding layer 4.

In some embodiments, the display panel includes a display region and a peripheral region surrounding the display region.

In implementations, the pixel is in the display region, that is, the light-emitting device, the pixel driving circuit, the first opening region, the second opening region and the color conversion portion are all located in the display region.

In implementations, the organic encapsulation sub-layer in the encapsulation layer is usually prepared in an inkjet printing process. Therefore, a plurality of blocking dam structures need to be arranged in the peripheral region. The orthographic projection of the blocking dam structures on the base substrate surrounds the display region. The blocking dam structures prevent the material of the organic encapsulation sub-layer in the encapsulation layer from overflowing. The blocking dam structure includes: a first sub-portion arranged in the same layer as the first pixel definition layer, and a second sub-portion arranged in the same layer as the second pixel definition layer. Some of the blocking dam structure also includes a third sub-portion located on the side of the second pixel definition layer away from the first pixel definition layer.

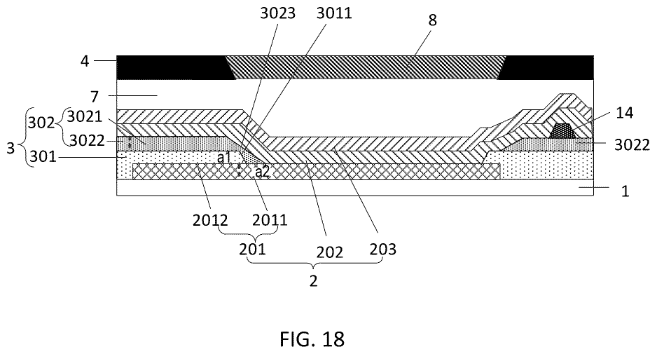

In some embodiments, as shown in FIG. 18, the display region further includes a spacer 14 located on a side of the second pixel definition layer 302 facing away from the base substrate 1.

In implementations, the spacer is arranged at the same layer as the third sub-section of the blocking dam.

In some embodiments, as shown in FIG. 18, the orthographic projection of the spacer 14 on the base substrate 1 is within the orthographic projection of the second pixel definition layer 302 on the base substrate 1.

Next, the method for preparing the display panel provided by embodiments of the present disclosure is described with examples. The method for preparing a display panel includes the following steps.
S101, forming a buffer layer on a base substrate.
S102, forming an active layer on a side of the buffer layer facing away from the base substrate, and forming a plurality of patterns of active layers by using a patterning process.
S103, forming a gate insulating layer on a side of the active layer facing away from the base substrate.
S104, forming a gate layer on a side of the gate insulating layer facing away from the base substrate, and patterning the gate layer in a patterning process to form a plurality of patterns of gates.
S105, forming an interlayer insulating layer on a side of the gates facing away from the base substrate.
S106, patterning the interlayer insulating layer and the gate insulating layer in a patterning process to form a plurality of first via holes and a plurality of second via holes penetrating the interlayer insulating layer and the gate insulating layer; the first via hole exposing part of the source region of the active layer, and the second via hole exposing part of the drain region of the active layer.
S107, forming a source-drain electrode layer on a side of the interlayer insulating layer facing away from the base substrate, and patterning the source-drain electrode layer in a patterning process to form a plurality of patterns of source electrodes and a plurality patterns of drain electrodes; the source electrode being electrically connected to the source region of the active layer through the first via hole, and the drain electrode being electrically connected to the drain region of the active layer through the second via hole.
S108, forming a planarization layer on a side of the source and drain electrodes facing away from the base substrate.
S109, patterning the planarization layer in a patterning process to form a plurality of third via holes in the planarization layer; the third via hole exposing part of the drain electrode.
S1010, forming an anode layer on a side of the planarization layer facing away from the base substrate, patterning the anode layer in a patterning process to form a plurality of patterns of anodes; the anode being electrically connected to the drain electrode through third via holes.
S1011, forming a first pixel definition layer on a side of the anodes facing away from the base substrate.
S1012, patterning the first pixel definition layer in a patterning process to form a plurality of first sub-opening regions in the first pixel definition layer, and forming a first sub-portion of the blocking dam structure in the peripheral region.
S1013, forming a second pixel definition layer on a side of the first pixel definition layer facing away from the base substrate, and patterning the second pixel definition layer in a patterning process to form a plurality of patterns of second pixel definition layers; the complete pixel definition layer consisting of the pattern of the second pixel definition layer and the pattern of the first pixel definition layer including a first opening region; the pattern of the second pixel definition layer including a first portion located in the display region and a second sub-portion of the blocking dam structure located in the peripheral region, or the pattern of the second pixel definition layer including the first portion, the second portion, and the second sub-portion of the blocking dam structure located in the peripheral region.
S1014, forming a spacer layer on a side of the second pixel definition layer facing away from the base substrate, and patterning the spacer layer to form a pattern of a spacer and a pattern of the third sub-portion of the blocking dam structure.
S1015, forming a light-emitting functional layer in the first opening region and on a side of the anodes facing away from the base substrate.
S1016, forming a pattern of a cathode on a side of the light-emitting functional layer facing away from the base substrate.
S1017, forming a pattern of a first inorganic encapsulation sub-layer on a side of the cathode facing away from the base substrate; the first inorganic encapsulation sub-layer being formed, for example, in a chemical vapor deposition process.
S1018, forming a pattern of an organic encapsulation sub-layer on a side of the first inorganic encapsulation sub-layer facing away from the base substrate; the organic encapsulation sub-layer being formed, for example, in an inkjet printing process.
S1019, forming a pattern of a second inorganic encapsulation sub-layer on a side of the organic encapsulation sub-layer facing away from the base substrate; the second inorganic encapsulation sub-layer being formed, for example, in a chemical vapor deposition process.
S1020, forming a light-shielding layer on a side of the second inorganic encapsulation sub-layer facing away from the base substrate, and patterning the light-shielding layer in a patterning process to form a plurality of second opening regions.
S1021, forming a plurality of patterns of color conversion portions in the second opening regions.
S1022, forming a pattern of a protective layer on a side of the color conversion portions and the light-shielding layer facing away from the base substrate.

Embodiments of the present disclosure provide a display apparatus, which includes the display panel provided by the embodiments of the present disclosure.

The display apparatus provided by embodiments of the present disclosure includes the above-mentioned display panel provided by embodiments of the present disclosure. The pixel definition layer includes two pixel definition layers with different side slope angles, that is, the angles between the side surfaces and the plane where the base substrate is located are different. The first angle of the first pixel definition layer is greater than the second angle of the second pixel definition layer. Only the cathode above the second side surface of the second pixel definition layer may form a small-angle diffraction grating. However, the orthographic projection of the light-shielding layer on the base substrate covers at least part of the orthographic projection of the second side surface on the base substrate. Accordingly, the light-shielding layer also shields the cathode above at least part of the second side surface, thereby blocking light reflected from the cathode above at least part of the second side surface, alleviating or even avoiding the color separation large aperture caused by interference, and improving the display effect of the display apparatus. In addition, the pixel definition layer is divided into two layers. The lower layer is the first pixel definition layer with a larger slope angle, and no diffraction grating will be formed in this region. The upper layer has a smaller slope angle to avoid cathode breakage, ensure the continuity of the cathode, avoid affecting the display panel production yield, and thus avoid affecting the yield of the display apparatus.

The display apparatus provided in the embodiments of the present disclosure is any product or component with a display function, such as a mobile phone, a tablet computer, a television, a monitor, a laptop computer, a digital photo frame, and a navigator. Other essential components of the display apparatus should be understood by those skilled in the art and will not be described in detail here, nor should they be construed as limiting the present disclosure. The implementation of the display apparatus can refer to the above-mentioned embodiments of the display panel, and the repeated parts are not repeated here.

To summarize, in the display panel and display apparatus provided by the embodiments of the present disclosure, the pixel definition layer includes two pixel definition layers having different side slope angles, i.e., angles between the side surfaces and the plane where the base substrate is located. The first angle of the first pixel definition layer is greater than the second angle of the second pixel definition layer, and only the cathode above the second side surface of the second pixel definition layer may form a small-angle diffraction grating. However, the orthographic projection of the light-shielding layer on the base substrate covers at least part of the orthographic projection of the second side surface on the base substrate. Accordingly, the light-shielding layer also shields the cathode above at least part of the second side surface, thereby blocking light reflected from the cathode above at least part of the second side surface, alleviating or even avoiding the color separation large aperture caused by interference, and improving the display effect. In addition, the pixel definition layer is divided into two layers. The lower layer is the first pixel definition layer with a larger slope angle, which will not form a diffraction grating in this region. The upper layer has a smaller slope angle to avoid cathode breakage, ensure the continuity of the cathode, and avoid affecting the display panel production yield.

Although preferred embodiments of the present invention have been described, additional changes and modifications to these embodiments may occur to those skilled in the art once the basic inventive concepts become known. Therefore, it is intended that the appended claims be interpreted as including the preferred embodiment and all changes and modifications that fall within the scope of the present invention.

Obviously, those skilled in the art can make various changes and modifications to the present disclosure without departing from the spirit and scope of the present disclosure. Thus, if these modifications and variations of the present disclosure fall within the scope of the claims of the present disclosure and their equivalents, the present disclosure is intended to include these modifications and variations.

1. A display panel, comprising:
a base substrate;
a plurality of light-emitting devices, located on a side of the base substrate and comprising an anode, a light-emitting functional layer, and a cathode which are stacked;
a pixel definition layer, located on a side of the cathode facing the base substrate and comprising a plurality of first opening regions; wherein the pixel definition layer comprises:
a first pixel definition layer, and
a second pixel definition layer on a side of the first pixel definition layer facing away from the base substrate;
wherein in a region corresponding to the first opening region, the first pixel definition layer comprises a first side surface and the second pixel definition layer comprises a second side surface; wherein a first angle is provided between the first side surface and a plane where the base substrate is located, a second angle is provided between the second side surface and the plane where the base substrate is located, the first angle and the second angle are both greater than 0° and less than 90°, and the second angle is less than the first angle;
a light-shielding layer, located on a side of the light-emitting devices facing away from the base substrate and comprising a plurality of second opening regions; wherein an orthographic projection of the second opening regions on the base substrate overlaps with an orthographic projection of the first opening regions on the base substrate; and an orthographic projection of the light-shielding layer on the base substrate covers at least part of an orthographic projection of the second side surface on the base substrate.

2. The display panel according to claim 1, wherein an orthographic projection of the second pixel definition layer on the base substrate covers a part of an orthographic projection of the first side surface on the base substrate.

3. The display panel according to claim 2, further comprising:
a plurality of driving transistors between the base substrate and the light-emitting devices; wherein the anode comprises:
a first region, and
a second region connected to the first region at an edge of the first region;
wherein an area of the first region is larger than an area of the second region; the second region is electrically connected to a drain of the driving transistor, an orthographic projection of the first pixel definition layer on the base substrate covers an orthographic projection of the second region on the base substrate; the orthographic projection of the first opening region on the base substrate is within an orthographic projection of the first region on the base substrate;
wherein the second pixel definition layer comprises a first portion; an orthographic projection of the first portion on the base substrate covers the orthographic projection of the second region on the base substrate.

4. The display panel according to claim 3, wherein the first portion covers a part of the first side surface.

5. The display panel according to claim 4, wherein the second pixel definition layer further comprises a second portion located outside the first portion;
an orthographic projection of the second portion on the base substrate is within the orthographic projection of the first pixel definition layer on the base substrate.

6. The display panel according to claim 5, wherein the orthographic projection of the second portion on the base substrate and the orthographic projection of the first side surface on the base substrate do not overlap with each other.

7. The display panel according to claim 6, wherein the orthographic projection of the light-shielding layer on the base substrate covers the orthographic projection of the second portion on the base substrate.

8. The display panel according to claim 5, wherein a distance between the orthographic projection of the second portion on the base substrate and the orthographic projection of the first side surface on the base substrate is greater than or equal to a distance between the orthographic projection of the first side surface on the base substrate and the orthographic projection of the light-shielding layer on the base substrate.

9. The display panel according to claim 8, wherein the orthographic projection of the light-shielding layer on the base substrate and a part of the orthographic projection of the first portion on the base substrate do not overlap with each other, and the orthographic projection of the light-shielding layer on the base substrate is within the orthographic projection of the first pixel definition layer on the base substrate.

10. The display panel according to claim 4, wherein the orthographic projection of the light-shielding layer on the base substrate covers at least part of the orthographic projection of the first side surface on the base substrate.

11. The display panel according to claim 10, wherein an orthographic projection of the part of the first side surface covered by the first portion of the second pixel definition layer on the base substrate is covered by the orthographic projection of the light-shielding layer on the base substrate.

12. The display panel according to claim 11, wherein a distance between the orthographic projection of the light-shielding layer on the base substrate and the orthographic projection of the first portion on the base substrate is greater than or equal to 0.

13. The display panel according to claim 1, wherein the display panel comprises a plurality of pixels arranged in an array;
the pixels comprise multiple types of sub-pixels, the sub-pixels comprise the light-emitting devices, and the second opening regions corresponding to different types of sub-pixels emit light of different colors;
in some adjacent pixels, patterns of the first portion corresponding to the same type of sub-pixels are centrosymmetric.

14. The display panel according to claim 13, wherein in each adjacent four pixels in a 2×2 array, patterns of the first portion corresponding to the same type of sub-pixels are centrosymmetric.

15. The display panel according to claim 1, wherein the first pixel definition layer comprises an inorganic material and the second pixel definition layer comprises an organic material.

16. The display panel according to claim 1, wherein in a direction perpendicular to the base substrate, a maximum thickness of the first pixel definition layer is greater than or equal to 0.5 micrometers and less than or equal to 1 micrometer;
the first angle is greater than 45° and less than 75°.

17. (canceled)

18. The display panel according to claim 1, wherein in a direction perpendicular to the base substrate, a maximum thickness of the first pixel definition layer is greater than or equal to 0.3 micrometers and less than or equal to 0.5 micrometers;
the first angle is greater than 75°.

19. (canceled)

20. The display panel according to claim 1, wherein in a direction perpendicular to the base substrate, a maximum thickness of the second pixel definition layer is greater than 0 and less than or equal to 1 micrometer.

21. The display panel according to claim 20, wherein the second angle is greater than 20° and less than 30°.

22. A display apparatus comprising the display panel according to claim 1.
